(19) United States
(12) Patent Application Publication
(10) Pub. No.: US 2026/0271764 A1
(43) Pub. Date: Sep. 10, 2026

(54) METHOD FOR POLISHING A RESIN FILM, AND METHOD FOR MANUFACTURING A CIRCUIT CONNECTION BODY

(71) Applicant: Resonac Corporation, Tokyo (JP)

(72) Inventors: Tetsuya OGAWA, Tokyo (JP); Shintaro NAGAYAMA, Tokyo (JP); Taira ONUMA, Tokyo (JP)

(73) Assignee: Resonac Corporation, Tokyo (JP)

(21) Appl. No.: 19/480,012

(22) PCT Filed: Aug. 8, 2024
(86) PCT No.: PCT/JP2024/028498

§ 371 Date: Oct. 29, 2025

(51) Int. Cl. H10W 72/00; H10W 72/90; H10W 80/00; H10W 90/00; H10W 90/26

(52) U.S. Cl. CPC H10W 72/01961; H10W 72/952; H10W 80/312; H10W 80/327; H10W 90/26; H10W 90/792

(57) ABSTRACT

A method for polishing a resin film, comprising: semi-curing a thermosetting resin film comprising a maleimide compound having a maleimide group, by heat treatment; and polishing the semi-cured resin film by chemical mechanical polishing while supplying an abrasive comprising silica particles. A method for manufacturing a circuit connection body, comprising polishing a resin film.

### TECHNICAL FIELD

The present disclosure relates to a method for polishing a resin film and a method for manufacturing a circuit connection body.

### BACKGROUND ART

In three-dimensional packaging of semiconductor chips, application of hybrid bonding, in which an insulating film is bonded together with electrodes, has been considered for finer wiring. It has also been proposed to form an insulating film for hybrid bonding using a resin material such as polyimide (Patent Literature 1).

On the other hand, it is known that a composition comprising a maleimide compound and an allyl compound is thermoset by an addition reaction including an ene reaction and a Diels-Alder reaction, or by radical polymerization (Non Patent Literature 1).

### CITATION LIST

### Patent Literature

Patent Literature 1: International Publication No. WO 2020/085183

### Non Patent Literature

Non Patent Literature 1: Handbook of Thermoset Plastics, Third Edition, 2014, p. 459-510

### SUMMARY OF INVENTION

### Technical Problem

An organic insulating film formed of a resin material is expected to be advantageous compared to an inorganic insulating film in terms of reducing the influence of debris and the like. A resin film used as an organic insulating film may be formed by a method including a step of chemical mechanical polishing (CMP) for planarization or the like. A resin film can generally be polished at an appropriate polishing rate by CMP using an abrasive containing alumina particles as abrasive grains. However, the surface of a resin film polished by CMP using an abrasive containing alumina particles tends to have a large surface roughness.

The present disclosure relates to a method for polishing a resin film that can polish the resin film at an appropriate polishing rate and form a surface having a sufficiently small surface roughness.

### Solution to Problem

The present disclosure includes the following.

[1]

A method for polishing a resin film, comprising:
semi-curing a thermosetting resin film comprising a maleimide compound having a maleimide group, by heat treatment; and
polishing the semi-cured resin film by chemical mechanical polishing while supplying an abrasive comprising silica particles.
   [2]

The method according to [1], wherein a cure rate of the semi-cured resin film by the heat treatment is 90% or less,
the cure rate is a value calculated by the formula:

$$Cure rate [ \% ] = 100 - ( {Q}_{1} / {Q}_{0} ) \times 100$$

where Q₀ is a calorific value [J/g] by a curing reaction in the resin film before the heat treatment, and Q₁ is a calorific value [J/g] by a curing reaction in the resin film after the heat treatment.
   [3]

The method according to [1] or [2], wherein the resin film before the heat treatment further comprises a reactive component that reacts with the maleimide compound.

[4]

The method according to [3], wherein the reactive component comprises at least one compound selected from the group consisting of a styrenic compound, an allyl compound having an allyl group, a phenol compound having a phenolic hydroxyl group, and a benzoxazine compound having a benzoxazine group, wherein the styrenic compound has a reactive group that is a group resulting from removal of at least one hydrogen atom bonded to a benzene ring from a compound represented by the following formula (IV):

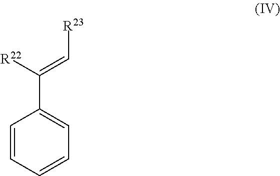

where R²² and R²³ are each independently a hydrogen atom or an alkyl group having 1 to 3 carbon atoms.
   [5]

The method according to any one of [1] to [4], wherein the resin film is provided to cover an electrode, and
by polishing the resin film by the chemical mechanical polishing, a part of the resin film is removed such that the electrode is exposed.
   [6]

The method according to any one of [1] to [5], further comprising further curing the resin film by heating the polished resin film.

[7]

A method for manufacturing a circuit connection body, the circuit connection body comprising a first circuit member having a first electrode and a second circuit member having a second electrode,
the method comprising:
preparing the first circuit member, the first circuit member having the first electrode and a first insulating film, the first insulating film forming an opening, and the first electrode being provided in the opening; and
bonding the first circuit member having the first electrode and the first insulating film and the second circuit member by hybrid bonding such that the first electrode and the second electrode are electrically connected, the second circuit member having the second electrode and a second insulating film, the second insulating film forming an opening, and the second electrode being provided in the opening,
wherein preparing the first circuit member comprises:
forming a thermosetting first resin film that comprises a maleimide compound having a maleimide group, includes a portion provided around the first electrode, and covers the first electrode; and
polishing the first resin film by the method according to any one of [1] to [5], wherein by polishing the first resin film, a part of the first resin film is removed such that the first electrode is exposed, and the polished first resin film is the first insulating film.
   [8]

A method for manufacturing a circuit connection body, the circuit connection body comprising a first circuit member having a first electrode and a second circuit member having a second electrode,
the method comprising:
preparing the first circuit member, the first circuit member having the first electrode and a first insulating film, the first insulating film forming an opening, and the first electrode being provided in the opening;
preparing the second circuit member, the second circuit member having the second electrode and a second insulating film, the second insulating film forming an opening, and the second electrode being provided in the opening; and
bonding the first circuit member having the first electrode and the first insulating film and the second circuit member having the second electrode and the second insulating film by hybrid bonding such that the first electrode and the second electrode are electrically connected,
wherein preparing the first circuit member comprises:
forming a thermosetting first resin film that comprises a maleimide compound having a maleimide group, includes a portion provided around the first electrode, and covers the first electrode; and
polishing the first resin film by the method according to any one of [1] to [5],
wherein by polishing the first resin film, a part of the first resin film is removed such that the first electrode is exposed, and the polished first resin film is the first insulating film, and
wherein preparing the second circuit member comprises:
forming a thermosetting second resin film that comprises a maleimide compound having a maleimide group, includes a portion provided around the second electrode, and covers the second electrode; and
polishing the second resin film by the method according to any one of [1] to [5],
wherein by polishing the second resin film, a part of the second resin film is removed such that the second electrode is exposed, and the polished second resin film is the second insulating film.

### Advantageous Effects of Invention

A method for polishing a resin film can be provided that can polish the resin film at an appropriate polishing rate and form a surface having a sufficiently small surface roughness.

### BRIEF DESCRIPTION OF DRAWINGS

FIG. 1 is a process diagram showing an example of a method for manufacturing a circuit connection body.

FIG. 2 is a process diagram showing an example of a method for manufacturing a circuit connection body.

FIG. 3 is a process diagram showing an example of a method for manufacturing a circuit connection body.

### DESCRIPTION OF EMBODIMENTS

The present invention is not limited to the following examples.

An example of a method for polishing a resin film comprises semi-curing a thermosetting resin film comprising a maleimide compound having a maleimide group, by heat treatment; and polishing the semi-cured resin film by chemical mechanical polishing (CMP) while supplying an abrasive comprising silica particles. The semi-cured resin film can be polished at a high polishing rate by CMP using an abrasive comprising silica particles, and moreover, the surface of the resin film after polishing can have a sufficiently small surface roughness.

The thermosetting resin film can be formed, for example, by applying a curable resin composition comprising a maleimide compound. The curable resin composition to be applied may contain a solvent. When a curable resin composition containing a solvent is used, the resin film can be formed by heating the applied curable resin composition to remove the solvent. The heating temperature for removing the solvent may be, for example, 60° C. or higher and 150° C. or lower. The resin film before the heat treatment and the curable resin composition may further comprise a reactive component that reacts with the maleimide compound. Details of the curable resin composition for forming the resin film will be described later. The thickness of the resin film may be, for example, 1 μm or more and 100 μm or less.

The formed resin film is subjected to a heat treatment. The heat treatment is adjusted to conditions such that the resin film is semi-cured without being fully cured. A resin film formed from a curable resin composition comprising a maleimide compound can be easily semi-cured by adjusting heating conditions such as temperature and time. The conditions for the heat treatment are adjusted, for example, within a temperature range of 100° C. or higher and 220° C. or lower, or 120° C. or higher and 180° C. or lower, and a heating time of 10 minutes or more and 120 minutes or less.

That the resin film has been semi-cured can be confirmed, for example, by observing an exotherm due to curing in a DSC thermogram obtained by differential scanning calorimetry of a sample of the resin film. In the case of a fully cured resin film or curable resin composition, an exotherm due to curing is substantially not observed. For example, a resin film exhibiting a cure rate of more than 0% and less than 100% can be regarded as a semi-cured resin film. The cure rate can be determined by differential scanning calorimetry. The cure rate in that case can be a value calculated by the formula:

Cure rate [%]=100−(Q₁/Q₀)×100.

Q₀ is a calorific value [J/g] by a curing reaction in the resin film before the heat treatment, and Q₁ is a calorific value [J/g] by a curing reaction in the resin film after the heat treatment. Q₀ and Q₁ can be determined from the area of the exothermic peak in the DSC thermogram obtained by differential scanning calorimetry at a heating rate of 10° C./min, and the mass of the measurement sample. The cure rate in the resin film semi-cured by the heat treatment may be 90% or less, 85% or less, or 80% or less, and may be 10% or more, 20% or more, 30% or more, 40% or more, 50% or more, 55% or more, or 60% or more.

The abrasive for CMP contains silica particles as abrasive grains. The silica particles may be colloidal silica. Other CMP conditions can be adjusted within the range of normal conditions. For example, the resin film can be polished by pressing the resin film against a rotating polishing pad while supplying the abrasive onto the polishing pad. By polishing the semi-cured resin film, a part of the resin film is removed from the surface at a sufficiently high polishing rate, and a surface having a small surface roughness is formed. The polishing time may be, for example, 10 seconds or more and 600 seconds or less.

The resin film may be provided to cover an electrode. In that case, by polishing the resin film by chemical mechanical polishing, a part of the resin film may be removed such that the electrode is exposed. By polishing the resin film, a planar surface including the resin film and the electrode may be formed. However, a step may be formed between the resin film and the electrode.

The polished resin film may be further cured by heating the resin film. The resin film may be subjected to bonding with other members or other processing, and then heated again to further advance the curing. The heating temperature for the reheating may be, for example, 220° C. or higher and 350° C. or lower. The cure rate of the resin film after reheating may be, for example, 90% or more and 100% or less.

The method for polishing a resin film exemplified above can be applied, for example, to the manufacturing of a circuit connection body having the resin film as an insulating film, or to the formation of a redistribution layer having the resin film as an insulating film.

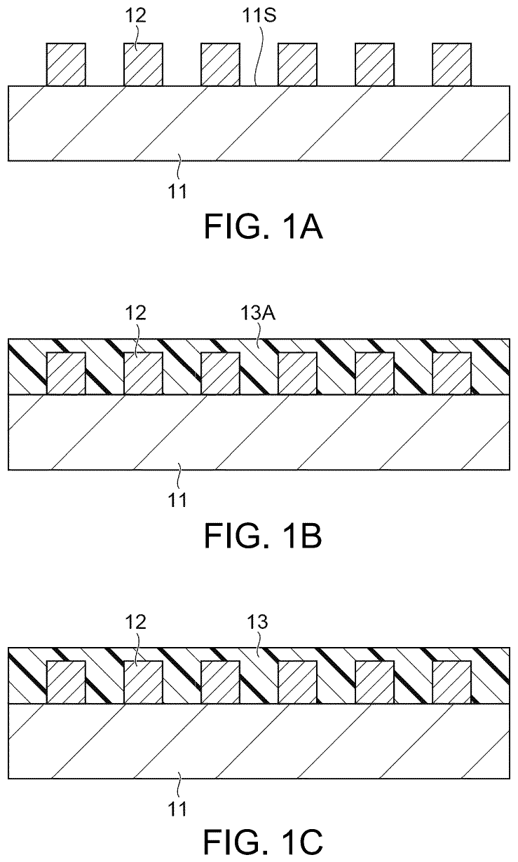

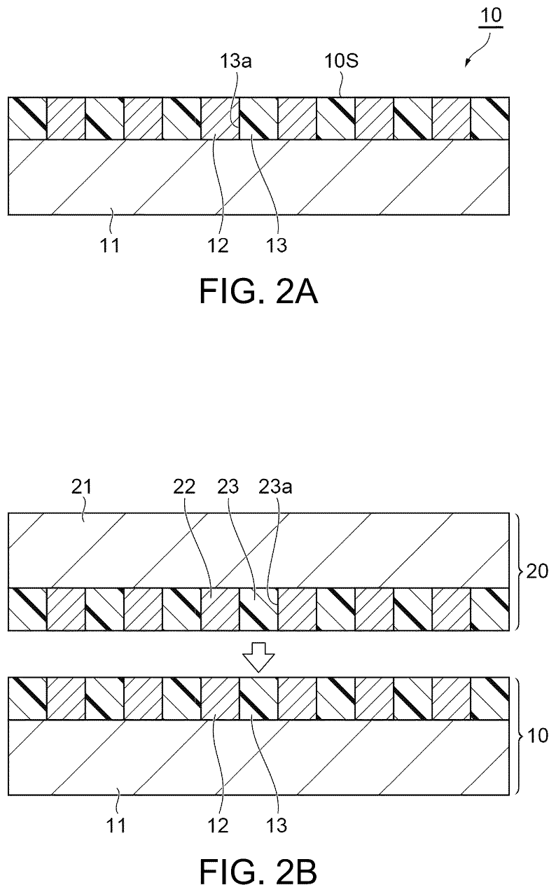

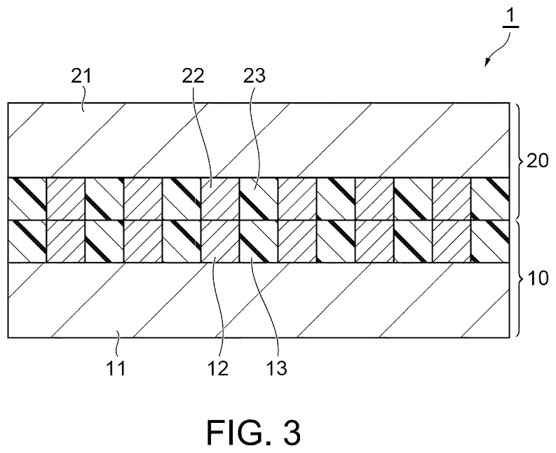

FIG. 1, FIG. 2, and FIG. 3 are process diagrams showing an example of a method for manufacturing a circuit connection body. The method shown in FIGS. 1 to 3 comprises preparing a first circuit member 10 having a first substrate 11, a first electrode 12, and a first insulating film 13; preparing a second circuit member 20 having a second substrate 21, a second electrode 22, and a second insulating film 23; and bonding the first circuit member 10 and the second circuit member 20 by hybrid bonding such that the first electrode 12 and the second electrode 22 are electrically connected. By this method, a circuit connection body 1, which is a bonded body of the first circuit member 10 and the second circuit member 20, is formed. In hybrid bonding, for example, the first circuit member 10 and the second circuit member 20 are heated and pressurized, whereby the first circuit member 10 and the second circuit member 20 are bonded such that the first insulating film 13 and the second insulating film 23 are bonded, and the first electrode 12 and the second electrode 22 are bonded.

At least one of the first substrate 11 and the second substrate 21 may be a semiconductor substrate having a circuit surface. In that case, a semiconductor device is obtained as the circuit connection body 1. Usually, an integrated circuit is provided on the circuit surface side of the semiconductor substrate. For example, the first substrate 11 may be a semiconductor wafer, and the second substrate 21 may be a semiconductor chip. A plurality of second circuit members 20 having semiconductor chips may be bonded to one first circuit member 10 having a semiconductor wafer. In that case, the semiconductor wafer (first substrate 11) of the obtained circuit connection body may be diced into a plurality of semiconductor chips. The semiconductor substrate may be, for example, a silicon substrate. When the first circuit member 10 or the second circuit member 20 is not a semiconductor substrate, they may be various wiring boards (for example, interposers).

The first circuit member 10 has a plurality of first electrodes 12, and the first insulating film 13 is provided around the first electrodes 12 and includes a portion that fills the gaps between the plurality of first electrodes 12. The first electrode 12 and the first insulating film 13 are provided on the first substrate 11. When the first substrate 11 is a semiconductor substrate having a circuit surface, the first electrode 12 and the first insulating film 13 are provided on the circuit surface. The first insulating film 13 forms a plurality of openings 13a, which are through-holes exposing the first substrate 11, and the first electrodes 12 are provided in the openings 13a.

The second circuit member 20 has a plurality of second electrodes 22, and the second insulating film 23 is provided around the second electrodes 22 and includes a portion that fills the gaps between the plurality of second electrodes 22. The second electrode 22 and the second insulating film 23 are provided on the second substrate 21. When the second substrate 21 is a semiconductor substrate, the second electrode 22 and the second insulating film 23 are provided on the circuit surface. The second insulating film 23 forms a plurality of openings 23a, which are through-holes exposing the second substrate 21, and the second electrodes 22 are provided in the openings 23a.

The first circuit member 10 is prepared by a method comprising: providing the first electrode 12 on a principal surface 11S of the first substrate as shown in (a) of FIG. 1; forming a thermosetting first resin film 13A on the principal surface 11S of the first substrate 11 on the side of the first electrode 12, as shown in (b) of FIG. 1; semi-curing the first resin film 13A by heat treatment as shown in (c) of FIG. 1; and exposing the first electrode 12 by polishing the first insulating film 13, which is the semi-cured first resin film 13A, as shown in (a) of FIG. 2.

The first electrode 12 is formed from a conductive material containing a metal such as copper. The first electrode 12 containing a metal can be formed by a normal method such as a plating method.

The first resin film 13A, which includes a portion provided around the first electrode 12 and covers the first electrode 12, can be formed by applying a curable resin composition comprising a maleimide compound. When a curable resin composition containing a solvent is used, the first resin film 13A can be formed by heating the applied curable resin composition to remove the solvent. The heating temperature for removing the solvent may be, for example, 60° C. or higher and 150° C. or lower. The first resin film 13A may be formed to cover the entire first electrode 12 while filling the gaps between the plurality of first electrodes 12. By the heat treatment of the formed first resin film 13A, the first resin film 13A is semi-cured to form the first insulating film 13. The first insulating film 13 before polishing comprises a semi-cured curable resin composition. The cure rate of the first insulating film 13 comprising the semi-cured curable resin composition may be within a range similar to the range exemplified for the cure rate in the semi-cured resin film.

Since the curing reaction of the first resin film 13A formed from the curable resin composition comprising a maleimide compound is mainly an addition reaction such as radical polymerization and a Diels-Alder reaction, it is less likely to generate volatiles originating from elimination components. In addition, many functional groups derived from maleimide groups and the like may be present on the surface of the first insulating film 13 formed from the curable resin composition comprising a maleimide compound. Therefore, the first insulating film 13 can exhibit good bondability without necessarily requiring an activation treatment such as a plasma treatment. In addition, it may be possible to adjust the polishing rate of the first insulating film 13 based on the crosslinking density and the like in the first insulating film 13.

The conditions for the heat treatment of the first resin film 13A for forming the first insulating film 13 are adjusted so that the first resin film 13A is semi-cured. For example, the temperature of the heat treatment may be 100° C. or higher and 220° C. or lower, or 120° C. or higher and 180° C. or lower. The time of the heat treatment may be, for example, 10 minutes or more and 120 minutes or less.

The first insulating film 13 (semi-cured first resin film) is polished by CMP using an abrasive containing silica particles. By the polishing, a part of the first insulating film 13 is removed from the side opposite to the first substrate 11, such that an opening 13a exposing the first electrode 12 is formed. The surface of the tip of the first electrode 12 (the surface on the side opposite to the first substrate 11) may be planarized by the polishing. Due to the difference in polishing rates, in the first circuit member 10 after polishing, the height of the first electrode 12 may be greater than the thickness of the first insulating film 13. The difference between the height of the first electrode 12 and the thickness of the first insulating film 13 may be adjusted in consideration of the difference in the coefficient of linear thermal expansion between the first electrode 12 and the first insulating film 13, and the like. The difference between the height of the first electrode 12 and the thickness of the first insulating film 13 may be, for example, 10 nm or more and 200 nm or less. The thickness of the first insulating film 13 may be, for example, 1 μm or more and 100 μm or less.

The second insulating film 23 of the second circuit member 20 can be an organic insulating film or an inorganic insulating film. When the second insulating film 23 is an organic insulating film, the second circuit member can be prepared by a method similar to that for the first circuit member 10, including heat treatment of a second resin film comprising a curable resin composition, and polishing of the second insulating film. When both the first insulating film 13 and the second insulating film 23 are organic insulating films formed from a curable resin composition comprising a maleimide compound, particularly good bondability is likely to be expressed. The first insulating film 13 and the second insulating film 23 can be formed from the second resin film using the same or different curable resin compositions.

The shapes of the first electrode 12 and the second electrode 22 are not particularly limited, but some or all of these electrodes are arranged such that the first electrode 12 and the second electrode 22 face each other and are bonded. The width of the first electrode 12 and the second electrode 22 may be, for example, 1 μm or more or 100 μm or more, and may be 300 m or less or 30 μm or less. The width here means the maximum width of each electrode in a direction parallel to the principal surface (circuit surface) of the first substrate 11 or the second substrate 21. The interval between adjacent first electrodes 12 and the interval between adjacent second electrodes 22 may be, for example, 1 μm or more or 100 μm or more, and may be 300 μm or less or 30 μm or less. The height of the first electrode 12 and the second electrode 22 may be, for example, 1 μm or more or 10 μm or more, and may be 100 μm or less or 10 μm or less. The height of the first electrode 12 may be the same as or different from the thickness of the first insulating film 13. The height of the second electrode 22 may be the same as or different from the thickness of the second insulating film 23.

From the viewpoint of bondability between the electrodes, the surface of the tip of the first electrode 12 may have a surface roughness Ra of 1 nm or less. The surface of the tip of the second electrode 22 may also have a similar surface roughness Ra. Here, the surface roughness Ra is the arithmetic mean roughness (Ra) defined in JIS B 0601-2001.

As shown in (e) of FIG. 2, the prepared first circuit member 10 and second circuit member 20 are aligned such that the first electrode 12 and the second electrode 22 to be bonded face each other. Subsequently, as shown in FIG. 3, by heating and pressurizing the first circuit member 10 and the second circuit member 20, the first circuit member 10 and the second circuit member 20 are bonded by hybrid bonding such that the first electrode 12 and the second electrode 22 are bonded, and the first insulating film 13 and the second insulating film 23 are bonded.

The bonding of the first electrode 12 and the second electrode 22, and the bonding of the first insulating film 13 and the second insulating film 23 may proceed simultaneously or sequentially. For example, after heating and pressurizing mainly for bonding the first insulating film 13 and the second insulating film 23, the first circuit member 10 and the second circuit member 20 may be further heated and pressurized to bond the first electrode 12 and the second electrode 22. The first insulating film 13 and/or the second insulating film 23 may be further cured during the heating and pressurizing for bonding the first circuit member 10 and the second circuit member 20. The first insulating film 13 and/or the second insulating film 23 may be further cured by heating after bonding.

The conditions for heating and pressurizing for bonding are adjusted so that the insulating film and the electrode are appropriately bonded. For example, the heating temperature for bonding may be 150° C. or higher and 350° C. or lower, and the pressure for bonding may be 1.0 MPa or more and 5.0 MPa or less. The time for heating and pressurizing may be, for example, 10 seconds or more and 2 hours or less.

The curable resin composition used for forming the resin film (the first insulating film 13 and/or the second insulating film 23) in the method exemplified above comprises one or more maleimide compounds. A maleimide compound is a compound having one or more maleimide groups. From the viewpoint of heat resistance and reduction of the coefficient of thermal expansion of the insulating film, etc., the curable resin composition may comprise a maleimide compound having two or more maleimide groups.

The maleimide compound may have a maleimide group containing a nitrogen atom directly bonded to a cyclic group (e.g., an aromatic group). For example, the maleimide compound may comprise a compound represented by the following formula (Ia), (Ib), or (Ic).

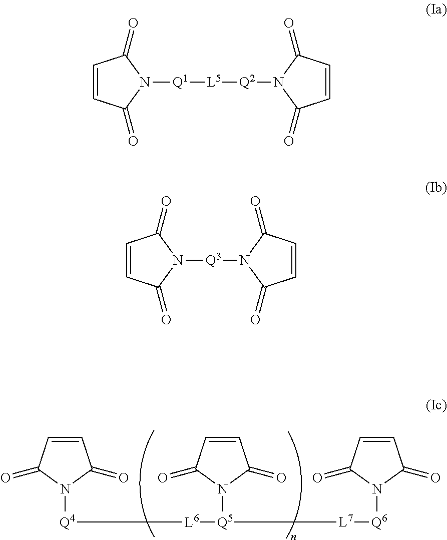

In formula (Ia), Q¹ and Q² are each independently a cyclic group which may have a substituent, and L⁵ is a divalent organic group or a single bond. Q¹ and Q² may each independently be an aromatic group (e.g., a phenylene group) which may have a substituent (e.g., an alkyl group having 1 to 3 carbon atoms). L⁵ may be a group containing one or more cyclic groups (excluding a maleimide group) which may have a substituent, selected from a monocyclic ring, a condensed ring, a non-condensed bridged ring, and a spiro ring; an alkylene group having 1 to 5 carbon atoms which may have a substituent (e.g., a methylene group, a propane-1,3-diyl group, a propane-2,2-diyl group); or a single bond. L⁵ may have two or more cyclic groups and a single bond or a divalent organic group (e.g., a methylene group which may have a substituent, a propane-2,2-diyl group which may have a substituent) connecting the two or more cyclic groups. L⁵ may further have a methylene group connecting the cyclic group and Q¹ or Q². L⁵ may have a cyclic group resulting from removal of one or more hydrogen atoms from benzene, 2,3-dihydro-1H-indene, or succinimide. Examples of the maleimide compound represented by formula (Ia) include a compound represented by the following formula (11). L⁵ in formula (11) is defined in the same manner as L⁵ in formula (Ia). R³¹ is an alkyl group having 1 to 3 carbon atoms, and p and q are each independently an integer of 0 to 4. A plurality of R³¹s in the same molecule may be the same or different.

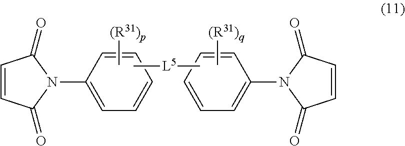

In formula (Ib), Q³ represents a cyclic group which may have a substituent. Q³ may be an aromatic group (e.g., a phenylene group). The cyclic group in Q³ may have a substituent such as an alkyl group having 1 to 3 carbon atoms.

In formula (Ic), Q⁴, Q⁵, and Q⁶ are each independently a cyclic group which may have a substituent, L⁶ and L⁷ are each independently a divalent organic group or a single bond, and n is an integer of 1 or more. Examples of Q⁴, Q⁵, and Q⁶ are the same as the examples of Q¹ and Q². Examples of L⁶ and L⁷ are the same as the examples of L⁵. Examples of the maleimide compound represented by formula (Ic) include a compound represented by the following formula (12). In formula (12), L⁶ and L⁷ are defined in the same manner as L⁶ and L⁷ in formula (Ic), and n is an integer of 1 or more.

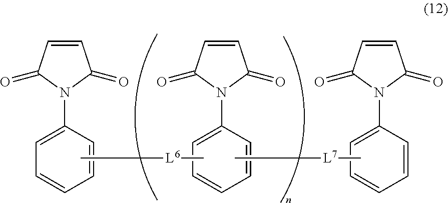

Specific examples of the maleimide compound include compounds represented by the following formulas 101, 102, 103, 104, or 105. In these formulas, n represents an integer of 1 or more.

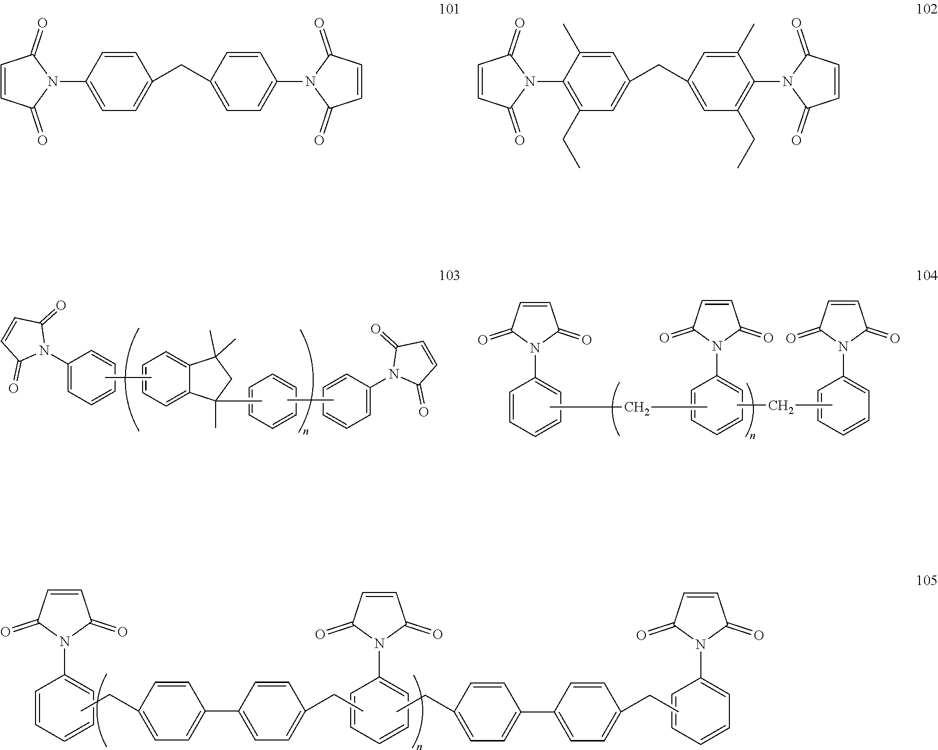

Examples of commercially available maleimide compounds include NE-X-9470S (trade name, DIC Corporation), MIR-3000-70MT (trade name, Nippon Kayaku Co., Ltd.), BMI-1000 (trade name, Daiwa Kasei Kogyo Co., Ltd.), BMI-2300 (trade name, Daiwa Kasei Kogyo Co., Ltd.), BMI-5100 (trade name, Daiwa Kasei Kogyo Co., Ltd.), BMI-80 (trade name, Daiwa Kasei Kogyo Co., Ltd.), BMI (trade name, Daiwa Kasei Kogyo Co., Ltd.), and SFR-2300MR-T (trade name, Resonac Corporation).

The maleimide group of the maleimide compound may be blocked by a blocking agent that dissociates upon heating. In other words, the curable resin composition may comprise a blocked maleimide compound having a blocked maleimide group. When the curable resin composition comprises a blocked maleimide compound, “maleimide compound” can be read as “blocked maleimide compound” in the following description.

The reactive component may comprise at least one compound selected from the group consisting of a styrenic compound, an allyl compound, a phenol compound, and a benzoxazine compound. The reactive component may comprise a styrenic compound and an allyl compound.

A styrenic compound is a compound having, as a reactive group, a group resulting from removal of one or more hydrogen atoms bonded to a benzene ring from a compound represented by the following formula (IV). In formula (IV), R²² and R²³ are each independently a hydrogen atom or an alkyl group having 1 to 3 carbon atoms (e.g., a methyl group). R²² may be a hydrogen atom, and R²³ may be a hydrogen atom or an alkyl group having 1 to 3 carbon atoms (e.g., a methyl group). The styrenic compound tends to react with the maleimide compound at a relatively low temperature. The styrenic compound and the maleimide compound can react by a Diels-Alder reaction.

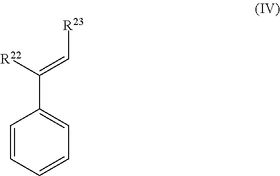

The styrenic compound may have a plurality of reactive groups. The reactive group of the styrenic compound is represented, for example, by the following formula (IVa) or (IVb). R²² and R²³ in formulas (IVa) and (IVb) are defined in the same manner as R²² and R² in formula (IV). R¹¹ and R¹² are an alkyl group having 1 to 3 carbon atoms, p is an integer of 0 to 3, and q is an integer of 0 to 4. A plurality of R¹¹s and R¹²s in the same molecule may be the same or different, respectively.

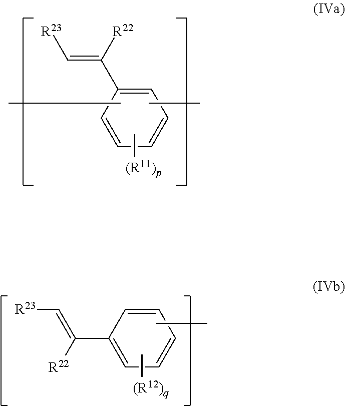

The styrenic compound may be a polymer comprising a structural unit represented by the following formula (41) or (42). R²² and R²³ in formulas (41) and (42) are defined in the same manner as R²² and R²³ in formula (IV). In formula (41), L¹ is a single bond or a divalent organic group, R¹¹ is an alkyl group having 1 to 3 carbon atoms (e.g., a methyl group), and p is an integer of 0 to 3. In formula (42), L² is a single bond or a divalent organic group, R¹² is an alkyl group having 1 to 3 carbon atoms (e.g., a methyl group), and q is an integer of 0 to 4.

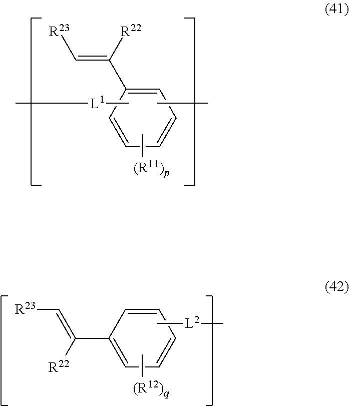

Examples of the divalent organic group as Lt or L² include an oxy group (—O—), —C(R¹⁶)(R¹⁷)—, a carbonyl group (—C(═O)—), a carbonyloxy group (—C(═O)O—), an amide group (—C(═O)NH—), a carbonate group (—OC(═O)O—), a sulfonyl group (—S(═O)₂—), and a thio group (—S—). R¹⁶ and R¹⁷ are each independently a hydrogen atom or an alkyl group having 1 to 3 carbon atoms.

The polymer as the styrenic compound may further comprise a structural unit represented by the following formula (43). In formula (43), L³ is a single bond or a divalent organic group, R¹³ is an alkyl group having 1 to 3 carbon atoms, and r is an integer of 0 to 4. Examples of the divalent organic group as L³ are the same as the examples of the divalent organic group for L¹ and L².

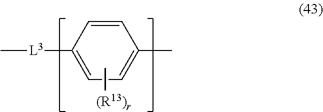

The styrenic compound may be a polymer comprising a structural unit represented by the following formula (401), or a polymer represented by the following formula (402). In formulas (401) and (402), R²², R²³, L, L², L³, R¹¹, R¹², R, p, q, and r are defined in the same manner as R²², R²³, L¹, L², L³, R¹¹, R¹², R, p, q, and r in formulas (41), (42), or (43). In formula (402), L¹¹, L¹², and L¹³ are each independently a single bond or a divalent organic group, R¹⁴ is an alkyl group having 1 to 3 carbon atoms (e.g., a methyl group), s is an integer of 0 to 4, and m and n are each independently an integer of 1 or more. Examples of the divalent organic group as L¹¹, L¹², or L¹³ are the same as the examples of the divalent organic group for L¹ or L². A plurality of R¹⁴s in the same molecule may be the same or different.

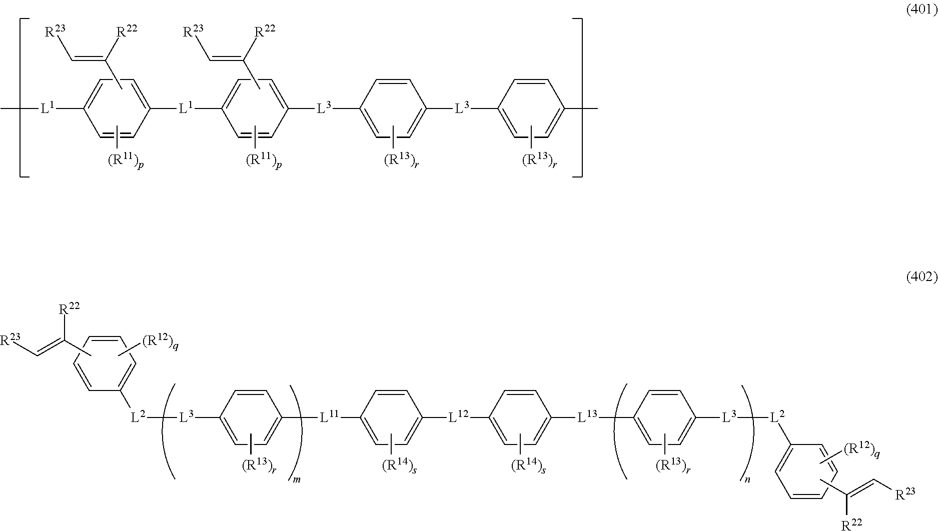

The molecular weight of the styrenic compound may be 200 or more and 100,000 or less. The weight-average molecular weight and/or number-average molecular weight of the styrenic compound may be 500 or more and 100,000 or less. In the present specification, the weight-average molecular weight and the number-average molecular weight can be values in terms of standard polystyrene measured by gel permeation chromatography.

The reactive component may comprise an allyl compound having an allyl group as a reactive group. An allyl compound is a compound having one or more allyl groups (2-propenyl group, —CH₂CH═CH₂). From the viewpoint of heat resistance and reduction of the coefficient of thermal expansion of the cured resin body, etc., the curable resin composition may comprise an allyl compound having two or more allyl groups.

The allyl compound may comprise a compound having a cyclic group and an allyl group or an allyloxy group directly bonded to the cyclic group. For example, the allyl compound in the curable maleimide resin composition may comprise a compound represented by the following formula (Va), (Vb), (Vc), or (Vd).

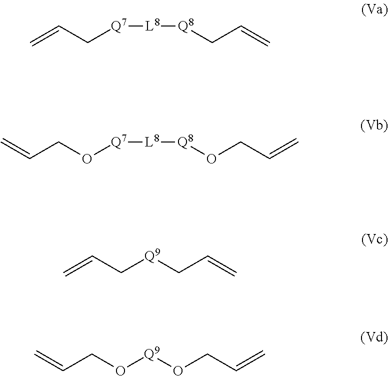

In formulas (Va) and (Vb), Q⁷ and Q⁸ each independently represent a cyclic group which may have a substituent, and L⁸ represents a divalent organic group or a single bond. Q⁷ and Q⁸ may each independently be a group resulting from removal of one or more hydrogen atoms from benzene, isocyanuric acid, or nadimide. L⁸ may be a group containing one or more cyclic groups (excluding a maleimide group) which may have a substituent, selected from a monocyclic ring, a condensed ring, a non-condensed bridged ring, and a spiro ring; a linear alkylene group which may have a substituent (e.g., a methylene group, a propane-1,3-diyl group); a propane-2,2-diyl group which may have a substituent; or a single bond. L⁸ may have two or more cyclic groups and a single bond or a divalent organic group (e.g., a methylene group which may have a substituent, a propane-2,2-diyl group which may have a substituent) connecting the two or more cyclic groups. L⁸ may further have a methylene group connecting the cyclic group and Q⁷ or Q⁸. The cyclic group in L⁸ may be substituted with a substituent selected from, for example, a methyl group, a hydroxy group, and an allyl group. L⁸ may have a phenylene group which may have a substituent.

In formulas (Vc) and (Vd), Q⁹ represents a cyclic group which may have a substituent. Q⁹ may be an aromatic group (e.g., a phenylene group) or a group resulting from removal of one or more hydrogen atoms from isocyanuric acid. The cyclic group in Q⁹ may be substituted with, for example, a methyl group or an allyl group.

Specific examples of the allyl compound include compounds represented by the following formulas 501, 502, 503, 504, 505, 506, 507, 508, or 509. In these formulas, n represents an integer of 1 or more.

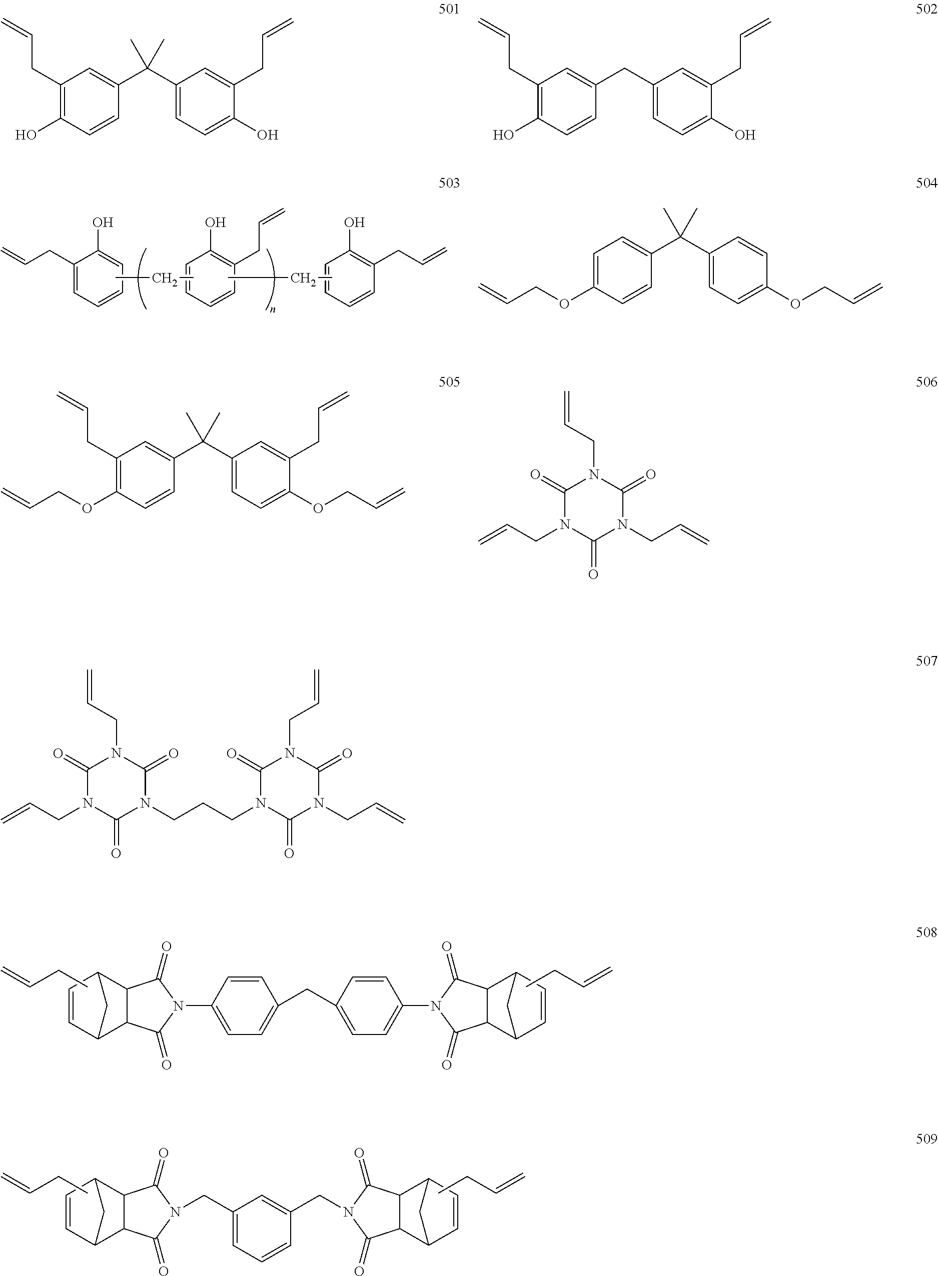

Examples of commercially available allyl compounds include DABPA (trade name, Kanto Chemical Co., Inc.), DA-BPF (trade name, Yokkaichi Gosei Co., Ltd.), LVA01 (trade name, Gunei Chemical Industry Co., Ltd.), BPA-AE (trade name, Konishi Chemical Ind. Co., Ltd.), BANI-X (trade name, Maruzen Petrochemical Co., Ltd.), BANI-M (trade name, Maruzen Petrochemical Co., Ltd.), FATC-809 (trade name, Gunei Chemical Industry Co., Ltd.), FATC-809AP (trade name, Gunei Chemical Industry Co., Ltd.), DAIC (trade name, Shikoku Chemicals Corporation), and DD-1 (trade name, Shikoku Chemicals Corporation).

The curable resin composition may comprise an allyl compound having a reactive group represented by the following formula (5) (hereinafter sometimes referred to as an “allylamino compound”). The allylamino compound may have a plurality of reactive groups represented by formula (5). The allylamino compound tends to react with a bismaleimide compound at a relatively low temperature.

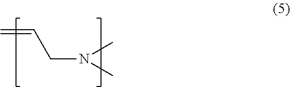

The allylamino compound may be a compound represented by the following formula (50). In formula (50), R²⁴ and R² are each independently a hydrogen atom or a monovalent organic group, and R²⁴ and R²⁵ may be bonded to each other to form a cyclic group.

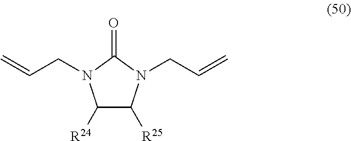

The monovalent organic group as R²⁴ or R²⁵ may be a hydrocarbon group which may have a substituent (e.g., an alkyl group having 1 to 6 carbon atoms). R²⁴ and R²⁵ may be bonded to each other to form a 4- to 8-membered cyclic group. Specific examples of the allylamino compound include a compound represented by the following formula 510.

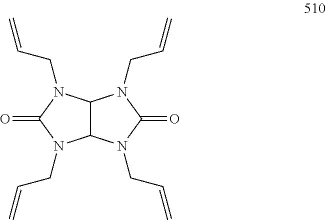 [SMILES: C=CCN1C(=O)N(CC=C)C2C1N(CC=C)C(=O)N2CC=C]

A phenol compound is a compound having a phenolic hydroxyl group as a reactive group. A benzoxazine compound is a compound having a benzoxazine group. The benzoxazine compound can generate a phenolic hydroxyl group as a reactive group upon heating.

The content of the reactive component may be 10% by mass or more and 80% by mass or less, based on the total amount of the maleimide compound and the reactive component. The content of the reactive component may be 15% by mass or more, 20% by mass or more, 25% by mass or more, or 30% by mass or more, and may be 75% by mass or less, 70% by mass or less, 65% by mass or less, or 60% by mass or less, based on the total amount of the maleimide compound and the reactive component. The total content of the maleimide compound and the reactive component may be 50% by mass or more, 60% by mass or more, 70% by mass or more, 80% by mass or more, or 90% by mass or more, and may be 100% by mass or less, based on the total amount of components of the curable resin composition excluding the solvent.

The curable resin composition may further comprise a solvent that dissolves or disperses the maleimide compound and the reactive component. Examples of the solvent include γ-butyrolactone, cyclohexanone, cyclopentanone, mesitylene, N,N-dimethylformamide, propylene glycol monomethyl ether acetate, and ethyl lactate. The content of the solvent may be, for example, 10% by mass or more and 300% by mass or less, based on the total amount of the maleimide compound and the reactive component.

The curable resin composition may further comprise a component that initiates or promotes the reaction of the maleimide compound and the reactive component.

The curable resin composition may further comprise a component that reduces the dielectric tangent of the cured resin body (insulating film) (hereinafter referred to as a “dielectric tangent modifier”). The dielectric tangent modifier includes, for example, an aromatic compound represented by the following formula (VIa), (VIb), or (VIc).

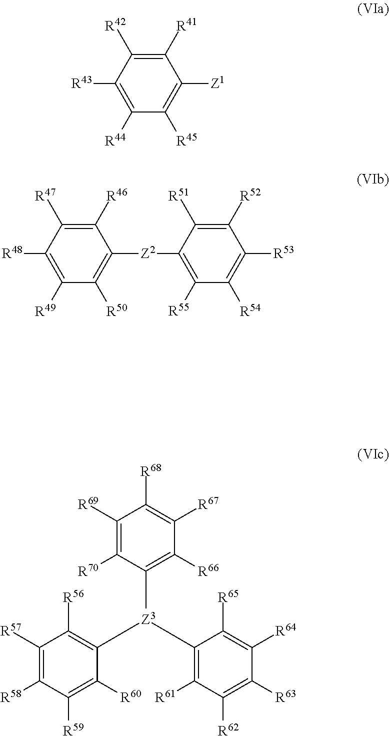

In formula (VIa), R⁴¹, R⁴⁴, and R⁴⁵ each independently represent a hydrogen atom, a methyl group, or a t-butyl group; R⁴² and R⁴³ each independently represent a hydrogen atom, a hydroxy group, or an organic group having 1 to 30 carbon atoms; and Z¹ represents an organic group having 7 to 80 carbon atoms containing at least one heteroatom selected from the group consisting of sulfur, phosphorus, oxygen, and nitrogen, or an organic group having 2 to 15 carbon atoms containing a carbonyl group.

In formula (VIb), R⁴⁶, R⁴⁹, R⁵⁰, R⁵¹, R⁵², and R⁵⁵ each independently represent a hydrogen atom, a methyl group, or a t-butyl group; R⁴⁷, R⁴⁸, R⁵³, and R⁵⁴ each independently represent a hydrogen atom, a hydroxy group, or an organic group having 1 to 30 carbon atoms; and Z² represents a divalent organic group having 1 to 50 carbon atoms containing at least one heteroatom selected from the group consisting of sulfur, phosphorus, oxygen, and nitrogen, or a divalent organic group having 1 to 75 carbon atoms.

In formula (VIc), R⁵⁶, R⁵⁹, R⁶⁰, R⁶¹, R⁶⁴, R⁶⁵, R⁶⁶, R⁶⁷, and R⁷⁰ each independently represent a hydrogen atom, a methyl group, or a t-butyl group; R⁵⁷, R⁵¹, R⁶², R⁶³, R⁶⁸, and R⁶⁹ each independently represent a hydrogen atom, a hydroxy group, or an organic group having 1 to 30 carbon atoms; and Z³ represents a trivalent organic group having 1 to 50 carbon atoms containing at least one heteroatom selected from the group consisting of sulfur, phosphorus, oxygen, and nitrogen, or a trivalent organic group having 1 to 50 carbon atoms.

The content of the dielectric tangent modifier may be 1% by mass or more and 50% by mass or less, based on the total amount of the maleimide compound and the reactive component. The content of the dielectric tangent modifier may be 2% by mass or more or 5% by mass or more, and may be 50% by mass or less or 40% by mass or less, based on the total amount of the maleimide compound and the reactive component.

The curable resin composition may further comprise an adhesion promoter. The adhesion promoter may include, for example, a silane coupling agent, an aluminum-based adhesion promoter, or a combination thereof.

Examples of the silane coupling agent include γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride, and N-phenylaminopropyltrimethoxysilane.

Examples of the aluminum-based adhesion promoter include aluminum tris(ethyl acetoacetate), aluminum tris(acetylacetonate), and ethyl acetoacetate aluminum diisopropylate.

The content of the adhesion promoter may be, for example, 0.5% by mass or more and 25% by mass or less, based on the total amount of the maleimide compound and the reactive component.

The curable resin composition may further comprise a polymerization inhibitor. Examples of the polymerization inhibitor include hydroquinone, N-nitrosodiphenylamine, p-tert-butylcatechol, 4-methoxyphenol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, and N-nitroso-N-(1-naphthyl)hydroxylamine ammonium salt.

The content of the polymerization inhibitor may be 0.005% by mass or more and 12% by mass or less, based on the total amount of the maleimide compound and the reactive component.

The curable resin composition may further comprise an azole compound. Examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole.

The content of the azole compound may be 0.1% by mass or more and 20% by mass or less, or 0.5% by mass or more and 5% by mass or less, based on the total amount of the maleimide compound and the reactive component.

The curable resin composition may comprise a hindered phenol compound. Examples of the hindered phenol compound include 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4 -hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, and 1,3,5-tris(4-t-butyl-5-ethyl-3-hydroxy-2-methylbenzyl)-1,3,5-triazine-2,4,6-(1H,3H,5H)-trione.

The content of the hindered phenol compound may be 0.1% by mass or more and 20% by mass or less, or 0.5% by mass or more and 10% by mass or less, based on the total amount of the maleimide compound and the reactive component.

The curable resin composition may comprise an organotitanium compound. The organotitanium compound may be, for example, a titanium chelate compound having two or more alkoxy groups, a tetraalkoxytitanium compound, a titanocene compound, a monoalkoxytitanium compound, a titanium oxide compound, a titanium tetraacetylacetonate compound, a titanate coupling agent, or a combination thereof.

Examples of the titanium chelate compound having two or more alkoxy groups include titanium bis(triethanolamine)diisopropoxide, titanium di(n-butoxide)bis(2,4-pentanedionate), titanium diisopropoxide bis(2,4-pentanedionate), titanium diisopropoxide bis(tetramethylheptanedionate), and titanium diisopropoxide bis(ethyl acetoacetate).

Examples of the tetraalkoxytitanium compound include titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyl oxide), titanium tetra(n-propoxide), titanium tetrastearyloxide, and titanium tetrakis[bis{2,2-(allyloxymethyl)butoxide}].

Examples of the titanocene compound include pentamethylcyclopentadienyltitanium trimethoxide, bis(η5-2,4-cyclopentadien-1-yl)bis(2,6-difluorophenyl)titanium, and bis(η5-2,4-cyclopentadien-1-yl)bis(2,6-difluoro-3-(1H-pyrrol-1-yl)phenyl)titanium.

Examples of the monoalkoxytitanium compound include titanium tris(dioctyl phosphate)isopropoxide, and titaniumtris(dodecylbenzenesulfonate)isopropoxide.

Examples of the titanium oxide compound include titanium oxide bis(pentanedionate), titanium oxide bis(tetramethylheptanedionate), and phthalocyanine titanium oxide.

Examples of the titanium tetraacetylacetonate compound include titanium tetraacetylacetonate.

Examples of the titanate coupling agent include isopropyl tridodecylbenzenesulfonyl titanate.

The content of the organotitanium compound may be 0.05% by mass or more and 10% by mass or less, or 0.1% by mass or more and 2% by mass or less, based on the total amount of the maleimide compound and the reactive component.

### EXAMPLES

The present invention is not limited to the following examples.

### 1. Curable Resin Composition (Varnish)

Curable resin compositions A and B were prepared by mixing the following components in the formulation ratios (parts by mass) shown in Table 1.

### (A) Maleimide Compound A1

Phenylmethane maleimide (BMI-2300, Daiwa Kasei Kogyo Co., Ltd.)

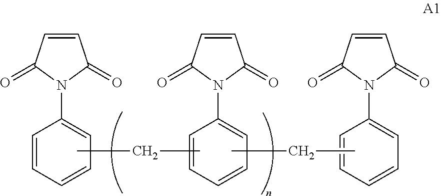

### (B) Reactive Component

### Allyl Compound B1

Aryl phenol resin (LVA01, Gunei Chemical Industry Co., Ltd.)

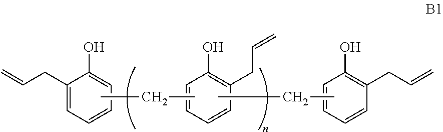

### Allyl Compound B2

1,3,4,6-tetraallylglycoluril (TA-G, Shikoku Chemicals Corporation)

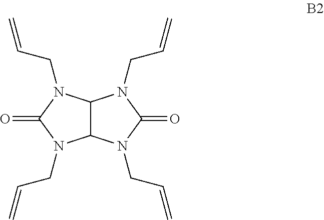 [SMILES: C=CCN1C(=O)N(CC=C)C2C1N(CC=C)C(=O)N2CC=C]

Styrenic compound B3

2,2′-diallylbisphenol A (Tokyo Chemical Industry Co., Ltd., 6.00 mmol, 1.85 g), 4,4′-difluorobenzophenone (Tokyo Chemical Industry Co., Ltd., 5.00 mmol, 1.09 g), and potassium carbonate (FUJIFILM Wako Pure Chemical Corporation, 30.0 mmol, 4.15 g) were placed in a three-necked flask. To this, N-methylpyrrolidone (30 mL) and toluene (15 mL) were added. A reflux condenser and a Dean-Stark trap were attached to the three-necked flask, and the system was placed under a nitrogen atmosphere. While stirring the reaction solution in the three-necked flask, the reaction solution was heated. After the internal temperature reached 155° C., stirring was continued for another 30 minutes to allow the reaction to proceed. Thereafter, the reaction solution in the three-necked flask was cooled to room temperature, and N-methylpyrrolidone (30 mL) was added thereto. After washing the reaction solution several times with water and ethanol, the styrenic compound B3 (white solid) was obtained by filtration (yield 85%, weight-average molecular weight 28,000). From the ¹H-NMR spectrum of the obtained styrenic compound B3, it was confirmed that a 1-propenyl group was generated.

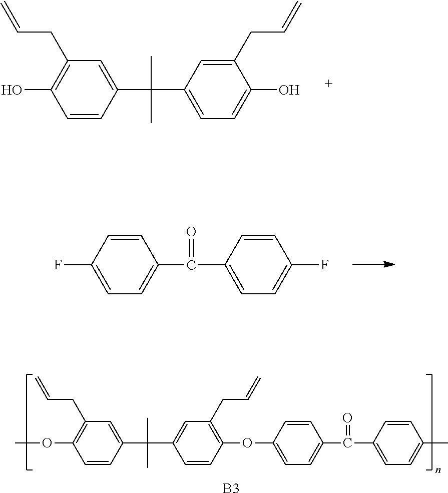

### (C) Silane Coupling Agent

C1: 3-aminopropyltriethoxysilane

### (D) Azole Compound

D1: 1,2,3-benzotriazole

### (E) Solvent

γ-butyrolactone (γ-BL)

| | | A | B |
|---|---|---|---|
| Maleimide compound | A1 | 51 | 63 |
| A1 | | | |
| Reactive component | B1 | 49 | — |
| | B2 | — | 16 |
| | B3 | — | 34.7 |
| Silane coupling agent | C1 | 1.1 | 1.1 |
| Azole compound | D1 | 1.8 | 1.8 |
| Solvent | γ-BL | 55.4 | 61.2 |

### 2. Heat Treatment of Resin Film

The curable resin composition A or B was dropped onto a silicon wafer (diameter: 12 inches) and formed into a film by spin coating. The solvent was removed from the coating film by heating at 110° C. for 3 minutes to form a resin film. Subsequently, the resin film was heat-treated under the conditions shown in Table 2 in a nitrogen atmosphere.

### 3. Cure Rate

The cure rate of the resin film after the heat treatment was measured using a differential scanning calorimeter (DSC8500, manufactured by PerkinElmer, Inc.). The solvent was removed from the curable resin composition A or B by heating at 110° C. for 3 minutes. Approximately 10 mg of a sample of the curable resin composition A or B from which the solvent had been removed was sealed in an aluminum pan. The sample pan in which the sample was sealed was placed in the holder of the differential scanning calorimeter together with an empty sample pan. After holding at 0° C. for 15 minutes, the temperature was raised to 300° C. at a heating rate of 10° C./min to obtain a DSC thermogram of the curable resin composition. From the integral value of the area of the exothermic peak associated with the curing reaction in the DSC thermogram and the weighed value of the sample, the calorific value Q₀ [J/g] generated by the curing reaction was obtained. The Q₀ obtained here substantially corresponds to the calorific value in the curing reaction in the resin film before the heat treatment. Subsequently, approximately 10 mg collected from the resin film after the heat treatment was sealed in an aluminum pan, and a DSC thermogram was obtained under the same conditions as for the sample of the curable resin composition. From the obtained DSC thermogram, the calorific value Q₁ [J/g] generated by the curing reaction in the resin film after the heat treatment was obtained. The cure rate was calculated from the following calculation formula.

$$Cure rate [ \% ] = 100 - ( {Q}_{1} / {Q}_{0} ) \times 100$$

### 4. Polishing Test

The resin film after the heat treatment was polished by CMP under the following conditions.

Polishing apparatus: CMP polisher FREX300X (manufactured by Ebara Corporation) Polishing pad: Porous urethane pad IC-1010 (manufactured by Rohm and Haas Japan K.K.)
Polishing pressure: 3.0 psi
Platen speed: 87 rpm
Head speed: 93 rpm
Abrasive (slurry): Slurry containing colloidal silica, or slurry containing alumina particles
Abrasive supply rate: 300 mL/min
Polishing time: 60 seconds

### 5. Polishing Rate

The film thickness of the resin film before and after polishing was measured using an optical interference film thickness measurement device (device name: F40) manufactured by Filmetrics, Inc. The film thickness was measured at 79 points located at equal intervals on a line passing through the center of the silicon wafer surface, and the average value was calculated. The polishing rate was calculated by substituting the average value of the film thickness before polishing t₀ [μm], the average value of the film thickness after polishing t₁ [μm], and the polishing time T [min] into the following calculation formula.

$$Polishing rate [ μm / min ] = ( {t}_{0} - {t}_{1} ) / T$$

### 6. Surface Roughness

The surface roughness Ra (arithmetic mean roughness) of a 10 μm×10 μm area at a position 75 mm from the center of the resin film after polishing was measured using an atomic force microscope (manufactured by BRUKER Corporation, model number: InSight CAP).

TABLE 2

| | | Heat treatment | | | | |
|---|---|---|---|---|---|---|
| | Curable | | Curing/ | Polishing test | | |
| | resin | | Semi- | | Polishing | |
| | compo- | Temp./ | curing | | rate | Ra |
| | sition | Time | (Cure rate) | Abrasive | [μm/min] | [nm] |
| Comp. | A | 250° C./ | Curing | Alumina | 0.8 | 2.5 |
| Ex. 1 | | 60 min | (100%) | | | |
| Comp. | A | 250° C./ | Curing | Silica | 0.0 | 0.4 |
| Ex. 2 | | 60 min | (100%) | | | |
| Ex. 1 | A | 175° C./ | Semi- | Silica | 0.8 | 0.5 |
| | | 45 min | curing | | | |
| | | | (76.4%) | | | |
| Comp. | B | 250° C./ | Curing | Silica | 0.0 | 0.4 |
| Ex. 3 | | 60 min | (100%) | | | |
| Ex. 2 | B | 155° C./ | Semi- | Silica | 1.4 | 0.5 |
| | | 90 min | curing | | | |
| | | | (67.1%) | | | |
| Ex. 3 | B | 155° C./ | Semi- | Silica | 1.5 | 0.5 |
| | | 45 min | curing | | | |
| | | | (64.4%) | | | |
| Ex. 4 | B | 150° C./ | Semi- | Silica | 1.8 | 0.6 |
| | | 45 min | curing | | | |
| | | | (60.3%) | | | |
| Ex. 5 | B | 120° C./ | Semi- | Silica | 6.0 | 1.1 |
| | | 30 min | curing | | | |
| | | | (50.9%) | | | |

The evaluation results are shown in Table 2. In each Example, it was confirmed that by polishing the semi-cured resin film by CIVP using an abrasive containing silica particles, a surface having a small surface roughness could be formed at a sufficiently high polishing rate. In the case of the resin films of Comparative Examples 2 and 3 with a cure rate of 100%, polishing substantially did not proceed by CMP using an abrasive containing silica particles.

### REFERENCE SIGNS LIST

1 . . . circuit connection body, 10 . . . first circuit member, 11 . . . first substrate, 12 . . . first electrode, 13 . . . first insulating film, 13a, 23a . . . opening, 13A . . . first resin film, 20 . . . second circuit member, 21 . . . second substrate, 22 . . . second electrode, 23 . . . second insulating film.

1. A method for polishing a resin film, comprising:
semi-curing a thermosetting resin film comprising a maleimide compound having a maleimide group, by heat treatment; and
polishing the semi-cured resin film by chemical mechanical polishing while supplying an abrasive comprising silica particles.

2. The method according to claim 1, wherein a cure rate of the semi-cured resin film by the heat treatment is 90% or less, the cure rate is a value calculated by the formula:
$$Cure rate [ \% ] = 100 - ( {Q}_{1} / {Q}_{0} ) \times 100$$
where Q₀ is a calorific value [J/g] by a curing reaction in the resin film before the heat treatment, and Q₁ is a calorific value [J/g] by a curing reaction in the resin film after the heat treatment.

3. The method according to claim 1, wherein the resin film before the heat treatment further comprises a reactive component that reacts with the maleimide compound.

4. The method according to claim 3, wherein the reactive component comprises at least one compound selected from the group consisting of a styrenic compound, an allyl compound having an allyl group, a phenol compound having a phenolic hydroxyl group, and a benzoxazine compound having a benzoxazine group, wherein the styrenic compound has a reactive group that is a group resulting from removal of at least one hydrogen atom bonded to a benzene ring from a compound represented by the following formula (IV): 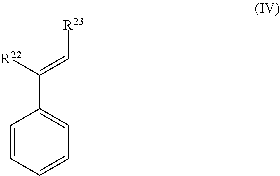
where R²² and R²³ are each independently a hydrogen atom or an alkyl group having 1 to 3 carbon atoms.

5. The method according to claim 1, wherein the resin film is provided to cover an electrode, and
by polishing the resin film by the chemical mechanical polishing, a part of the resin film is removed such that the electrode is exposed.

6. The method according to claim 1, further comprising further curing the resin film by heating the polished resin film.

7. A method for manufacturing a circuit connection body, the circuit connection body comprising a first circuit member having a first electrode and a second circuit member having a second electrode,
the method comprising:
preparing the first circuit member, the first circuit member having the first electrode and a first insulating film, the first insulating film forming an opening, and the first electrode being provided in the opening; and
bonding the first circuit member having the first electrode and the first insulating film and the second circuit member by hybrid bonding such that the first electrode and the second electrode are electrically connected, the second circuit member having the second electrode and a second insulating film, the second insulating film forming an opening, and the second electrode being provided in the opening,
wherein preparing the first circuit member comprises:
forming a thermosetting first resin film that comprises a maleimide compound having a maleimide group, includes a portion provided around the first electrode, and covers the first electrode; and
polishing the first resin film by the method according to claim 1,
wherein by polishing the first resin film, a part of the first resin film is removed such that the first electrode is exposed, and the polished first resin film is the first insulating film.

8. A method for manufacturing a circuit connection body, the circuit connection body comprising a first circuit member having a first electrode and a second circuit member having a second electrode,
the method comprising:
preparing the first circuit member, the first circuit member having the first electrode and a first insulating film, the first insulating film forming an opening, and the first electrode being provided in the opening;
preparing the second circuit member, the second circuit member having the second electrode and a second insulating film, the second insulating film forming an opening, and the second electrode being provided in the opening; and
bonding the first circuit member having the first electrode and the first insulating film and the second circuit member having the second electrode and the second insulating film by hybrid bonding such that the first electrode and the second electrode are electrically connected,
wherein preparing the first circuit member comprises:
forming a thermosetting first resin film that comprises a maleimide compound having a maleimide group, includes a portion provided around the first electrode, and covers the first electrode; and
polishing the first resin film by the method according to claim 1,
wherein by polishing the first resin film, a part of the first resin film is removed such that the first electrode is exposed, and the polished first resin film is the first insulating film, and
wherein preparing the second circuit member comprises:
forming a thermosetting second resin film that comprises a maleimide compound having a maleimide group, includes a portion provided around the second electrode, and covers the second electrode; and
polishing the second resin film by the method according to claim 1,
wherein by polishing the second resin film, a part of the second resin film is removed such that the second electrode is exposed, and the polished second resin film is the second insulating film.
